(19) United States
(12) Patent Application Publication
(10) Pub. No.: US 2024/0113074 A1
(43) Pub. Date: Apr. 4, 2024

(54) SEMICONDUCTOR PACKAGE

(71) Applicant: SAMSUNG ELECTRONICS CO., LTD., Suwon-si (KR)

(72) Inventors: Heewoo AN, Suwon-si (KR); Sangsub SONG, Suwon-si (KR); Kihong JEONG, Suwon-si (KR)

(21) Appl. No.: 18/374,437

(22) Filed: Sep. 28, 2023

(30) Foreign Application Priority Data
Oct. 4, 2022 (KR) 10-2022-0126587

(51) Int. Cl. H01L 25/065; H01L 23/00

(52) U.S. Cl. CPC H01L 25/0652; H01L 24/32; H01L 24/48; H01L 24/73; H01L 2224/32145; H01L 2224/32225; H01L 2224/48149; H01L 2224/48229; H01L 2224/73265; H01L 2924/1431; H01L 2924/1438

(57) ABSTRACT

Provided is a semiconductor package including a first substrate having an upper surface and a lower surface, and including a substrate pad arranged on the upper surface, a first chip stacked structure mounted on the upper surface of the first substrate, and including a plurality of first chips offset-stacked in a first direction, a lowermost first wire electrically connecting a lowermost first chip to the substrate pad, and a second chip stacked structure mounted on the upper surface of the first substrate, and including a plurality of second chips offset-stacked in the first direction, wherein the second chip stacked structure is spaced apart from the first chip stacked structure with the lowermost first wire therebetween in a horizontal direction, and an upper surface of a lowermost second chip is at a higher vertical direction level than a highest level of the lowermost first wire in a vertical direction.

### CROSS-REFERENCE TO RELATED APPLICATION

This application is based on and claims priority under 35 U.S.C. § 119 to Korean Patent Application No. 10-2022-0126587, filed on Oct. 4, 2022 in the Korean Intellectual Property Office, the disclosure of which is incorporated by reference herein in its entirety.

### BACKGROUND

### 1. Field

Embodiments relate to a semiconductor package, and more particularly, to a semiconductor package including a chip stacked structure.

### 2. Description of the Related Art

Recently, a demand for portable devices has rapidly increased in the electronic products market. Accordingly, miniaturization and a reduction of weight of electronic components mounted on electronic products has been continuously desired. To achieve miniaturization and light weight of electronic components, semiconductor packages mounted on electronic components must be able to process a large amount of data while decreasing the volume of electronic components and semiconductor packages.

Accordingly, it is desirable that the position and structure of a chip stacked structure be optimally designed to implement a high integration semiconductor package.

### SUMMARY

According to embodiments, there is provided a semiconductor package including a first substrate having an upper surface and a lower surface opposite to the upper surface, and including a substrate pad arranged on the upper surface, a first chip stacked structure mounted on the upper surface of the first substrate, and including a plurality of first chips offset-stacked in a first direction, a lowermost first wire electrically connecting a lowermost first chip at a lowermost end among the plurality of first chips to the substrate pad, and a second chip stacked structure mounted on the upper surface of the first substrate, and including a plurality of second chips offset-stacked in the first direction, wherein the second chip stacked structure is apart from the first chip stacked structure with the lowermost first wire therebetween in a horizontal direction, and an upper surface of a lowermost second chip at a lowest end among the plurality of second chips is at a higher vertical direction level than a highest level of the lowermost first wire in a vertical direction.

According to other embodiments, there is provided a semiconductor package that includes a first substrate having an upper surface and a lower surface, the lower surface being opposite to the upper surface. The semiconductor package may include a plurality of substrate pads arranged on the upper surface, a first chip stacked structure mounted on the upper surface of the first substrate, a plurality of first chips offset-stacked in a first direction, a lowermost first wire electrically connecting a lowermost first chip at a lowermost end among the plurality of first chips to the substrate pad that is arranged adjacent to the lowermost first chip, a second chip stacked structure mounted on the upper surface of the first substrate and apart from the first chip stacked structure with the first wire therebetween in a horizontal direction, the second chip stacked structure including a plurality of second chips offset-stacked in the first direction, a third chip stacked structure mounted on the upper surface of the first substrate, and including a plurality of third chips offset-stacked in a second direction, a lowermost third wire electrically connecting a lowermost third chip at a lowermost end among the plurality of third chips to the substrate pad arranged adjacent to the lowermost third chip, and a fourth chip stacked structure mounted on the upper surface of the first substrate and apart from the third chip stacked structure with the third wire therebetween in the horizontal direction, the fourth chip stacked structure including a plurality of fourth chips offset-stacked in the second direction. An upper surface of a lowermost second chip at a lowest end among the plurality of second chips may be at a higher level in a vertical direction than a maximum height of the first wire in the vertical direction. An upper surface of a lowermost fourth chip at a lowest end among the plurality of fourth chips may be at a higher level in the vertical direction than a maximum height of the third wire in the vertical direction.

According other embodiments, there is provided a semiconductor package including a first substrate having an upper surface and a lower surface, the lower surface being opposite to the upper surface, and including a plurality of substrate pads arranged on the upper surface, an external connection terminal arranged under the lower surface of the first substrate, a first chip stacked structure including a plurality of first chips mounted on the upper surface of the first substrate and offset-stacked in a first direction. First chip pads may each be arranged on a region upwardly exposed on an upper surface of each of the plurality of first chips. A lowermost first wire may electrically connect a lowermost first chip at a lowermost end among the plurality of first chips to a substrate pad located adjacent to the lowermost first chip, a second chip stacked structure mounted on the upper surface of the first substrate and apart from the first chip stacked structure with the first wire therebetween in a horizontal direction. The second chip stacked structure may include a plurality of second chips offset-stacked in the first direction, and second chip pads each being located on a region upwardly exposed on an upper surface of each of the plurality of second chips. A third chip stacked structure may include a plurality of third chips mounted on the upper surface of the first substrate and offset-stacked in a second direction, and third chip pads each arranged on a region upwardly exposed on an upper surface of each of the plurality of third chips. A lowermost third wire may electrically connect a lowermost third chip at a lowermost end among the plurality of third chips to the substrate pad arranged adjacent to the lowermost third chip. A fourth chip stacked structure may include a plurality of fourth chips mounted on the upper surface of the first substrate, apart from the third chip stacked structure with the third wire therebetween in the horizontal direction, and offset-stacked in the second direction. Third chip pads may each be arranged on a region upwardly exposed on an upper surface of each of the plurality of fourth chips. An upper surface of a lowermost second chip at a lowest end among the plurality of second chips may be at a higher level in a vertical direction than a maximum height of the first wire in the vertical direction An upper surface of a lowermost fourth chip at a lowest end among the plurality of fourth chips may be at a higher level in a vertical direction than a maximum height of the third wire in the vertical direction. At least a portion of an upper surface of the lowermost first chip may overlap the second chip stacked structure in the vertical direction. At least a portion of an upper surface of the lowermost third chip may overlap the fourth chip stacked structure in the vertical direction.

### BRIEF DESCRIPTION OF THE DRAWINGS

Features will become apparent to those of skill in the art by describing in detail exemplary embodiments with reference to the attached drawings in which:

FIG. 1 is a schematic cross-sectional view of a semiconductor package according to an embodiment;

FIG. 2 is a schematic cross-sectional view of a semiconductor package according to an embodiment;

FIGS. 3A and 3B are schematic cross-sectional views of semiconductor packages according to embodiments;

FIGS. 4A and 4B are schematic cross-sectional views of semiconductor packages according to embodiments; and

FIGS. 5A and 5B are schematic cross-sectional views of semiconductor packages according to embodiments.

### DETAILED DESCRIPTION

Hereinafter, embodiments are described in detail with reference to the accompanying drawings. Identical reference numerals may be used for the same constituent elements in the drawings, and duplicate descriptions thereof are not repeated.

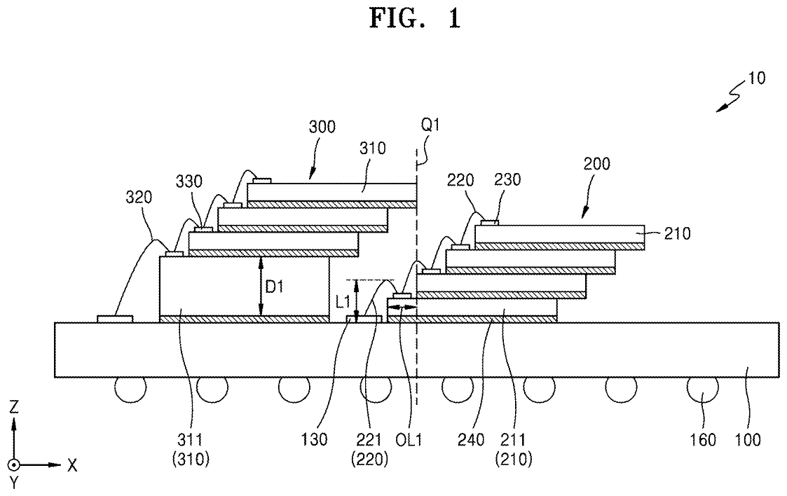

FIG. 1 is a schematic cross-sectional view of a semiconductor package 10 according to an embodiment.

Referring to FIG. 1, the semiconductor package 10 may include a first substrate 100, an external connection terminal 160, a substrate pad 130, a first chip stacked structure 200, and a second chip stacked structure 300.

The first substrate 100 may be located under the first chip stacked structure 200 and the second chip stacked structure 300. The first substrate 100 may be electrically connected to each of the first chip stacked structure 200 and the second chip stacked structure 300. for example, each of the first chip stacked structure 200 and the second chip stacked structure 300 may be mounted on an upper surface of the first substrate 100. According to some embodiments, the first substrate 100 may be, for example, a ceramic substrate, a printed circuit board (PCB), an organic substrate, an interposer substrate, etc. In addition, in some embodiments, the first substrate 100 may include a rewiring structure. In some embodiments, the first substrate 100 may include a body unit (not illustrated) and a wiring pattern (not illustrated). A portion of the wiring pattern may be exposed to a lower surface of the first substrate 100, and may function as a bump pad on which the external connection terminal 160 may be mounted.

Hereinafter, in the drawings, an X-axis direction and a Y-axis direction may represent directions in parallel with the upper surface or the lower surface of the first substrate 100 The X-axis direction and the Y-axis direction may be directions that are perpendicular to each other. A Z-axis direction may represent a direction perpendicular to a surface of the upper surface or the lower surface of the first substrate 100. For example, the Z-axis direction may include a direction perpendicular to an X-Y plane.

In addition, in the drawings below, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

According to some embodiments, the first substrate 100 may be, for example, a ceramic substrate, a PCB, an organic substrate, an interposer substrate, etc. In addition, in some embodiments, the first substrate 100 may include a rewiring structure.

The external connection terminal 160 may be under the lower surface of the first substrate 100. The external connection terminal 160 may be electrically connected to an external device, for example, a mother board, a PCB, a package substrate, etc. The external connection terminal 160 may be electrically connected to wiring patterns formed in the first substrate 100 via the substrate pad attached to the lower surface of the first substrate 100.

The external connection terminal 160 may include a solder ball. In some implementations, the external connection terminal 160 may have a structure including a pillar and a solder. The external connection terminal 160 may include at least one of copper (Cu), silver (Ag), gold (Au), or tin (Sb).

The substrate pad 130 may be arranged on the upper surface of the first substrate 100. Substrate pads 130 may be provided in plurality. In some embodiments, a plurality of substrate pads 130 may be arranged side by side along the second horizontal direction (Y) on the first substrate 100.

Some of the plurality of substrate pads 130 may be electrically connected to a first chip pad 230 via a first wire 220. Other ones of the substrate pads 130 may be electrically connected to a second chip pad 330 via a second wire 320. Herein, a singular form of constituent components may include a plural form unless the context clearly indicates otherwise.

The first chip stacked structure 200 may be arranged on the first substrate 100. The first chip stacked structure 200 may include a first chip 210, the first chip pad 230, and the first wire 220. The first chip stacked structure 200 may have a structure in which a plurality of first chips 210 are offset-stacked in the first direction. For example, the term “first chip stacked structure” may refer to a structure in which the plurality of first chips 210 are stacked in a cascade type configuration, for example, in a stair-like configuration or stair-type configuration, in the first direction.

According to some embodiments, the first direction may be the same as a first horizontal direction X, as an example. The first direction could also be a direction (−X) intersecting the first horizontal direction X, or a direction in parallel with a second horizontal direction Y. According to some embodiments, each of the first chips 210 may be arranged such that a surface thereof adjacent to an inactive surface of a semiconductor substrate faces the first substrate 100. For example, a lower surface of each of the first chips 210 may include a surface close to the inactive surface of the semiconductor substrate, and an upper surface of each of the first chips 210 may include a surface close to an active surface of the semiconductor substrate.

When the first chip stacked structure 200 is stacked in a stair type configuration in the first direction, a portion of the upper surface of each of the first chips 210 may be exposed. For example, a portion of an upper surface of each of the first chips 210 may not be covered by a first chip 210 that is stacked directly on an upper end thereof. When the first chips 210 are stacked in the first direction, portions of the upper surfaces of the first chips 210 opposite to the first direction may be upwardly exposed.

The first chip pad 230 may be arranged on the upper surface of each of the first chips 210. According to some embodiments, the first chip pad 230 may be arranged in a region in which a portion of the upper surface of the first chip 210 is upwardly exposed. According to some embodiments, a plurality of first chip pads 230 may be provided, and may be respectively arranged on regions upwardly exposed from the upper surfaces of the plurality of first chips 210. According to some embodiments, a plurality of first chip pads 230 may be arranged on the upper surface of one first chip 210. According to some embodiments, the first chip pads 230 may be arranged side by side in the second horizontal direction Y on the upper surface of the first chip 210.

The first wire 220 may be formed on one side of the first chip stacked structure 200. When the first chip stacked structure 200 is stacked in the first direction, the first wire 220 may be arranged in a direction opposite to the first direction. For example, the first wire 220 may be arranged on an upper surface side upwardly exposed from a lowermost first chip 211.

A plurality of first wires 220 may be provided. Some of the plurality of first wires 220 may electrically connect the substrate pad 130 to the first chip pad 230. Some of the plurality of first wires 220 may electrically connect the first chip pads 230 to each other at different levels in the vertical direction Z. In some implementations, the plurality of first wires 220 may be arranged in the second horizontal direction Y and electrically connect the substrate pad 130 to the first chip pad 230, or may electrically connect the first chip pads 230 to chip pads 230 having different levels in the vertical direction Z. A lowermost first wire 221, which is the first wire at the lowest end among the first wires 220, may electrically connect the lowermost first chip 211 to the first substrate 100.

The first wire 220 may include Au, Al, and Cu, as examples.

An adhesive layer 240 may be between the first substrate 100 and the lowermost first chip 211, or between first chips 210 that are stacked. In some embodiments, the adhesive layer 240 may include a layer attaching the first substrate 100 to the lowermost first chip 211, or attaching the first chips 210, which are sequentially stacked, to each other. Accordingly, the first chips 210 may be attached onto the first substrate 100 or onto a first chip 210 directly thereunder by using the adhesive layer 240.

The lowermost first chip 211, which is the chip at the lowermost end of the first chip stacked structure 200, may be bonded and fixed onto the upper surface of the first substrate 100 by using the adhesive layer 240. The first chip 210 stacked on the upper surface of the lowermost first chip 211 may be adhered and fixed onto the upper surface of the lowermost first chip 211 by applying the adhesive layer 240. Similarly, another first chip 210 stacked on a first chip 210 may also be adhered and fixed onto the upper surface of a first chip 210 that is directly under the other first chip 210 by using the adhesive layer 240.

The adhesive layer 240 may include a film having adhesive properties by itself. For example, the adhesive layer 240 may include a double-sided adhesive film. In some embodiments, the adhesive layer 240 may include a tape-shaped material layer, a liquid coating cured material layer, or a combination thereof. In addition, the adhesive layer 240 may include a thermal setting structure, a thermal plastic, an ultraviolet (UV)-cure material, or a combination thereof. The adhesive layer 240 may be referred to as a die attach film (DAF) or a non-conductive film (NCF).

The first chip 210 may include a semiconductor chip. According to some embodiments, the first chip 210 may be a memory chip or a logic chip. The memory chip may be, for example, a volatile memory semiconductor chip, such as a dynamic random access memory (RAM) (DRAM), or a static RAM (SRAM) or non-volatile memory chip, such as a phase-change RAM (PRAM), a magneto-resistive RAM (MRAM), ferroelectric RAM (FeRAM), or a resistive RAM (RRAM). The logic chip may include, for example, a microprocessor, an analog device, such as a central processing unit (CPU), a graphics processing unit (GPU), an application processor (AP), an analog element, or a digital signal processor.

In some embodiments, the first chip 210 may include a NAND flash memory chip The first chip stacked structure 200 may be mounted on the first substrate 100 in a structure in which a plurality of NAND flash memory chips are offset-stacked in the first direction.

The second chip stacked structure 300 may be arranged on the first substrate 100 spaced apart from the first chip stacked structure 200 in the first horizontal direction X. According to some embodiments, the second chip stacked structure 300 may be arranged in a direction opposite to the direction in which the first chips 210 are offset-stacked. For example, the second chip stacked structure 300 may be arranged on the first substrate 100 to be spaced apart from the first chip stacked structure 200 in the first horizontal direction X. The substrate pad 130 may be electrically connected to the first chip stacked structure 200. For example, the substrate pad 130 electrically may be connected to the lowermost first chip 211 therebetween. In addition, the second chip stacked structure 300 may be arranged on the first substrate 100 and may be spaced apart from the first chip stacked structure 200 in the first horizontal direction X with the lowermost first wire 221 therebetween.

The second chip stacked structure 300 may include a second chip 310, a second chip pad 330, and the second wire 320. The second chip stacked structure 300 may have a structure in which the plurality of second chips 310 are offset-stacked in the first direction. For example, a direction in which the plurality of second chips 310 of the second chip stacked structure 300 are offset-stacked may be substantially the same as a direction, in which the plurality of first chips 210 of the first chip stacked structure 200 are offset-stacked. Due to the offset-stacking, the second chip stacked structure 300 may have a structure in which the plurality of second chips 310 are stacked in a cascade type, that is, a stair type, in the first direction. The direction, in which the first chips 210 are offset-stacked may be the same as the direction, in which the second chips 310 are offset-stacked.

When the second chip stacked structure 300 is stacked in a stair type configuration in the first direction, a portion of the upper surface of each of the second chips 310 may be exposed. For example, a portion of an upper surface of each of the second chips 310 may not be covered by another second chip 310 stacked directly on an upper end of the second chip 310. When the second chips 310 are stacked in the first direction, portions of the upper surfaces of the second chips 310 opposite to the first direction may be upwardly exposed.

According to some embodiments, each of the second chips 310 may be arranged such that a surface thereof adjacent to an inactive surface of a semiconductor substrate faces the first substrate 100. For example, a lower surface of each of the second chips 310 may include a surface close to the inactive surface of the semiconductor substrate, and an upper surface of each of the second chips 310 may include a surface close to an active surface of the semiconductor substrate.

The second chip pad 330 may be arranged on the upper surface of each of the second chips 310. According to some embodiments, the second chip pad 330 may be arranged in a region in which a portion of the upper surface of the second chip 310 is upwardly exposed. According to some embodiments, a plurality of second chip pads 330 may be provided. The chip pads 330 may be respectively arranged on regions upwardly exposed from the upper surfaces of the plurality of second chips 310. According to some embodiments, a plurality of second chip pads 330 may be arranged on the upper surface of one second chip 310. According to some embodiments, the second chip pads 330 may be arranged side by side in the second horizontal direction Y on the upper surface of the second chip 310.

The second wire 320 may be formed on one side of the second chip stacked structure 300. When the second chip stacked structure 300 is stacked in the first direction, the second wire 320 may be arranged in a direction opposite to the first direction.

A plurality of second wires 320 may be provided. Some of the plurality of second wires 320 may electrically connect the substrate pad 130 to the second chip pad 330, and some of the plurality of second wires 320 may electrically connect the second chip pads 330 to each other at different levels in the vertical direction Z. In some implementations, the plurality of second wires 320 may be arranged in the second horizontal direction Y and may electrically connect the substrate pad 130 to the second chip pad 330, or electrically connect the second chip pads 330 to each other at different levels in the vertical direction Z.

The material and the configuration of the second wire 320 may be substantially the same as or similar to those of the first wire 220. Accordingly, descriptions thereof will not be repeated.

The adhesive layer 240 may be between the first substrate 100 and a lowermost second chip 311, or between the second chips 310 that are stacked. The material and configuration of the adhesive layer 240 may be substantially the same as or similar to that of the adhesive layer 240 described with reference to the first chip stacked structure 200. Thus, descriptions thereof are not repeated.

The second chip stacked structure 300 may be adhered to and fixed onto the upper surface of the first substrate 100 by using the adhesive layer 240. The second chips 310 may also be adhered to and fixed onto another second chip 310 directly thereunder by using the adhesive layer 240.

The second chip 310 may be or include a semiconductor chip. According to some embodiments, the second chip 310 may include a memory chip or a logic chip. In some embodiments, the second chip 310 may include a NAND flash memory chip. The second chip stacked structure 300 may be mounted on the first substrate 100 in a structure in which a plurality of NAND flash memory chips are offset-stacked in the first direction.

According to some embodiments, the second chip 310 may include the same type of chip as the first chip 210. According to some other embodiments, the second chip 310 and the first chip 210 may be different types of chips.

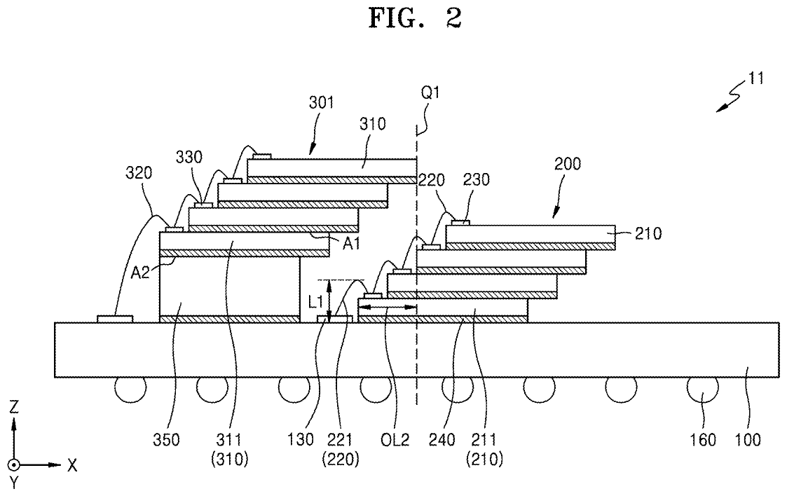

According to some embodiments, the lowermost second chip 311 may be arranged on the upper surface of the first substrate 100. An upper surface A1 (refer to FIG. 2) of the lowermost second chip 311 may be at a higher level in a vertical direction Z than the first height L1, which is a maximum height in the vertical direction Z of the first wire 220. In other words, the upper surface A1 of the lowermost second chip 311 may be at a higher level in a vertical direction Z than the first height L1, which is a maximum level in the vertical direction Z of the first wire 220.

According to some embodiments, the thickness of the lowermost second chip 311 in the vertical direction Z may be greater than the thickness of the second chips 310 in the vertical direction Z sequentially stacked on the lowermost second chip 311. To locate the upper surface A1 of the lowermost second chip 311 at a vertical level higher than the first height L1, the thickness of the lowermost second chip 311 in the vertical direction Z may be greater than the first height L1, which is the maximum height of the first wire 220 in the vertical direction Z. According to some embodiments, a thickness D1 of the lowermost second chip 311 in the vertical direction Z may range from about 500 μm to about 1000 as examples.

A portion of the first chip stacked structure 200 may overlap the second chip stacked structure 300 in the vertical direction. For example, when the semiconductor package 10 is viewed in the vertical direction Z, a portion of the first chip stacked structure 200 may be covered by a portion of the second chip stacked structure 300. In the drawings, a portion of the upper surface of the lowermost first chip 211 is illustrated as being overlapped by the second chip stacked structure 300 in the vertical direction Z. Portions of the upper surfaces of the first chips 210 stacked on the lowermost first chip 211 may be overlapped by the second chip stacked structure 300 in the vertical direction Z. According to some embodiments, a portion of the first chip stacked structure 200 may include the upper surface of the lowermost first chip 211. For example, at least a portion of the upper surface of the lowermost first chip 211 may be overlapped by the second chip stacked structure 300 in the vertical direction.

When a virtual line extending in the vertical direction from an end in the first direction of the second chip 310 stacked on the uppermost end of the second chip stacked structure 300 is defined as Q1, a shortest distance from a surface facing the lowermost second chip 311 in the lowermost first chip 211 to the Q1 may be defined as a first distance OL1. In this case, the first distance OL1 may be understood as a distance in the horizontal direction, in which the lowermost first chip 211 is overlapped by the second chip stacked structure 300.

In the drawings (for example, FIG. 1), although the first distance OL1 is illustrated as being shorter than a distance in the first horizontal direction X of the upper surface upwardly exposed of the lowermost first chip 211, the first distance OL1 may be longer due to a separation distance in the first horizontal direction X between the first chip stacked structure 200 and the second chip stacked structure 300, or due to the degree of offset-stacking between the first chip stacked structure 200 and the second chip stacked structure 300.

In the semiconductor package 10, the first chip stacked structure 200 and the second chip stacked structure 300 may be offset-stacked in the same direction, that is, in the first direction X. When the upper surface of the lowermost second chip 311 of the second chip stacked structure 300 is at a higher vertical direction Z level than a maximum height of the lowermost first wire 221 of the first chip stacked structure 200, the first distance OL1 may be increased. As the first distance OL1, that is, a portion of the lowermost first chip 211 overlapped by the second chip stacked structure 300 increases, widths in the horizontal directions X and Y of the semiconductor package 10 may decrease, and accordingly, the size of the semiconductor package 10 may decrease.

In the drawings, the number of chips in the first chip stacked structure 200 and in the second chip stacked structure 300 is illustrated as four. However, in some implementations, the first chip stacked structure 200 and the second chip stacked structure 300 may each include a different number of chips, such as two, three, or five or more chips. In addition, the numbers of chips of the first chip stacked structure 200 and the second chip stacked structure 300 may differ from each other.

FIG. 2 is a schematic cross-sectional view of a semiconductor package 11 according to an embodiment. Hereinafter, duplicate descriptions of the semiconductor package 10 provided with reference to FIG. 1 and the semiconductor package 11 provided with reference to FIG. 2 will not be repeated, and differences thereof will mainly be described.

Referring to FIG. 2, the semiconductor package 11 may include a first substrate 100, an external connection terminal 160, a substrate pad 130, a first chip stacked structure 200, and a second chip stacked structure 301.

According to some embodiments, the second chip stacked structure 301 may further include a first spacer 350. The first spacer 350 may be arranged on the upper surface of the first substrate 100. The first spacer 350 may be under the lowermost second chip 311. For example, the lowermost second chip 311 may be arranged on an upper surface of the first spacer 350. The lowermost second chip 311 may be spaced apart from the first substrate 100 in the vertical direction Z with the first spacer 350 therebetween. The first spacer 350 may be adhered and fixed onto the upper surface of the first substrate 100 by using the adhesive layer 240. Also, the lowermost second chip 311 may be adhered and fixed onto the upper surface of the first spacer 350 by using the adhesive layer 240.

The first spacer 350 may include, for example, a dummy chip, In some implementations, the first spacer may include a controller chip, etc.

An upper surface A2 of the first spacer 350 may be at a higher level in the vertical direction Z than the first height L1, which is the maximum height in the vertical direction Z of the first wire 220. For example, the upper surface A2 of the first spacer 350 may be at a level in the vertical direction that is higher than the highest level in the vertical direction of the first wire 220.

In some embodiments, a thickness in the vertical direction Z of the first spacer 350 may be in a range of, for example, about 500 μm to about 1000 μm.

A width in the first horizontal direction X of the first spacer 350 may be less than the width in the first horizontal direction X of the lowermost second chip 311. For example, the footprint of the first spacer 350 may be less than the footprint of the lowermost second chip 311. According to some embodiments, a sidewall opposite to a sidewall facing the first chip stacked structure 200 from the first spacer 350 may be substantially on the same plane as the sidewall of the lowermost second chip 311. That is, a sidewall opposite to the sidewall of the first spacer facing the first chip stacked structure 200 and a sidewall opposite to the sidewall of the lowermost second chip 311 facing the first chip stacked structure may be coplanar. The sidewall of the lowermost second chip 311 may be a sidewall facing the second wire 320. The first spacer 350 may contribute to forming space under the lowermost second chip 311.

Referring again to FIG. 1, a portion of the first chip stacked structure 200 may overlap the second chip stacked structure 300 in the vertical direction. For example, when the semiconductor package 10 is viewed in the vertical direction Z, a portion of the first chip stacked structure 200 may be covered by the second chip stacked structure 301. Referring to FIG. 2, according to some embodiments, at least a portion of the upper surface of the lowermost first chip 211 may overlap the second chip stacked structure 301 in the vertical direction. According to some embodiments, some portions of the upper surfaces of the first chips 210 stacked on the lowermost first chip 211 may also overlap the second chip stacked structure 301 in the vertical direction Z.

When a virtual line extending in the vertical direction from an end in the first direction of the second chip 310 stacked on the uppermost end of the second chip stacked structure 301 is defined as Q1, a shortest distance from a surface facing the lowermost second chip 311 in the lowermost first chip 211 to the Q1 may be defined as a second distance OL2. In this case, the second distance OL2 may be understood as a distance in the horizontal direction, in which the lowermost first chip 211 is overlapped by the second chip stacked structure 301.

According to some embodiments, the second distance OL2 may be further increased or decreased according to a separation distance in the first horizontal direction X between the first chip stacked structure 200 and the second chip stacked structure 301, or the degree of offset-stacking between the first chip stacked structure 200 and the second chip stacked structure 301.

The semiconductor package 11 according to embodiments may include a space in which the first chip stacked structure 200 overlaps the second chip stacked structure 301 in the vertical direction Z, which is achieved by adding the component of the first spacer 350. In addition, because the width of the first spacer 350 in the first horizontal direction X is less than the width of the lowermost second chip 311 in the first horizontal direction X, the first chip stacked structure 200 may be arranged to be close to the second chip stacked structure 301. Accordingly, the second distance OL2, which represents a portion of the first chip stacked structure 200 that overlaps the second chip stacked structure 301 in the vertical direction (Z), may be increased.

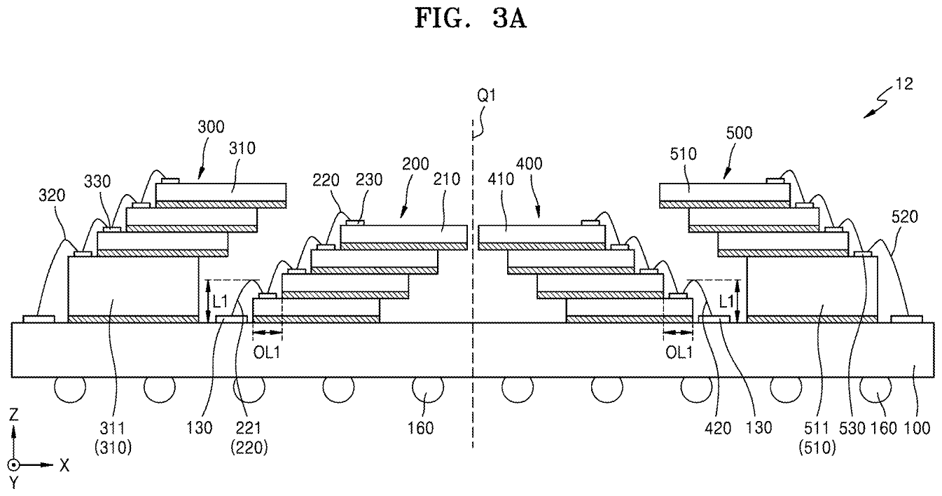

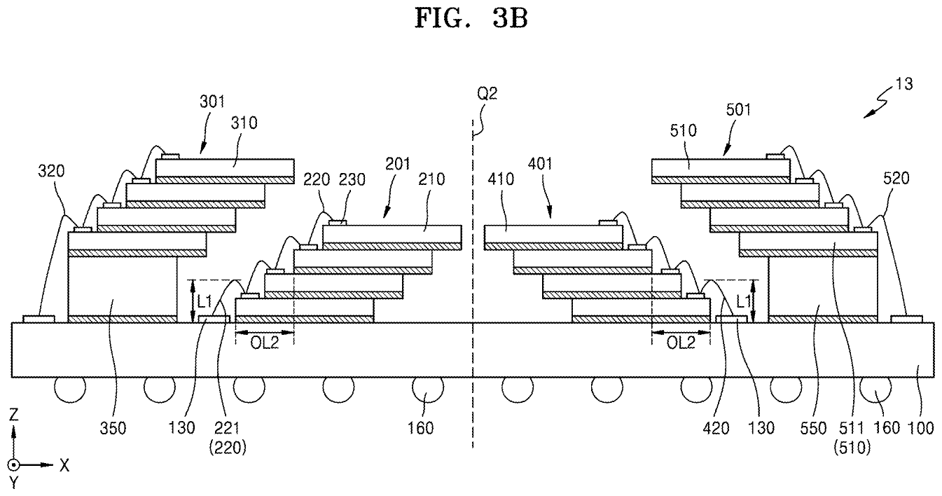

FIGS. 3A through 5B are schematic cross-sectional views of semiconductor packages 12, 13, 14, 15, 16, and 17 according to embodiments. Hereinafter, duplicate descriptions of the semiconductor package 10 given with reference to FIG. 1, the semiconductor package 11 given with reference to FIG. 2, and the semiconductor packages 12, 13, 14, 15, 16, and 17 given with reference to FIGS. 3A through 5B are not repeated, and differences thereof are mainly described.

Referring to FIGS. 3A through 5B, the semiconductor packages 12, 13, 14, 15, 16, and 17 may further include a third chip stacked structure 400 and a fourth chip stacked structure 500.

The third chip stacked structure 400 may be arranged on the first substrate 100. The third chip stacked structure 400 may include a third chip 410, a third chip pad 430, and a third wire 420. The third chip stacked structure 400 may have a structure in which the plurality of third chips 410 are offset-stacked in a second direction. For example, the third chip stacked structure 400 may have a structure in which the plurality of third chips 410 are stacked in a cascade type, that is, a stair type, in the second direction.

The second direction may be substantially the same as or opposite to the first direction in which the first chip stacked structure 200 and the second chip stacked structures 300 and 301 are offset-stacked. For example, in some embodiments, the first direction may be substantially the same as the second direction, and in some embodiments, the first direction and the second direction may be opposite to each other.

Because the third chip pad 430 and the third wire 420 are substantially the same as or similar to the first chip pad (refer to 230 in FIG. 1) and the first wire (refer to 220 in FIG. 1) is described with reference to FIGS. 1 and 2, respectively, detailed descriptions of the third chip pad and third wire or identification of such in the drawing figures are not necessary (refer instead to FIGS. 1 and 2) and descriptions thereof are not repeated.

Fourth chip stacked structures 500 and 501 may be arranged apart from the third chip stacked structure 400 on the first substrate 100 in the first horizontal direction X. According to some embodiments, the fourth chip stacked structures 500 and 501 may be arranged in a direction opposite to the second direction, the second direction being a direction in which the third chips 410 of the third chip stacked structure 400 are offset-stacked. For example, the fourth chip stacked structures 500 and 501 may be arranged on the first substrate 100, to be spaced apart from the third chip stacked structure 400 in the first horizontal direction X. The substrate pad 130 may be electrically connected to the third chip stacked structure 400. For example, the substrate pad 130 electrically connected to the lowermost first chip 211 therebetween. In addition, the fourth chip stacked structures 500 and 501 may be arranged on the first substrate 100 to be spaced apart from the third chip stacked structure 400 in the first horizontal direction X with the lowermost third wire 420 therebetween.

The fourth chip stacked structures 500 and 501 may include a fourth chip 510, a fourth chip pad 530, and a fourth wire 520. The fourth chip stacked structures 500 and 501 may have a structure in which a plurality of fourth chips 510 are offset-stacked in the second direction, the second direction being, for example, a direction, in which the plurality of fourth chips 510 of the fourth chip stacked structures 500 and 501 are offset-stacked. The second direction may be substantially the same as a direction in which the plurality of third chips 410 of the third chip stacked structures 400 and 401 are offset-stacked. Due to the offset-stacking, the fourth chip stacked structures 500 and 501 may have a structure in which the plurality of fourth chips 510 are stacked as a cascade type, for example, a stair type, in the second direction. For example, the direction in which the third chips 410 are offset-stacked may be the same as the direction, in which the fourth chips 510 are offset-stacked.

The third chip stacked structures 400 and 401 and the fourth chip stacked structures 500 and 501 may be adhered and fixed onto the first substrate 100 by using the adhesive layer 240. The third chips 410, which are sequentially stacked, or the fourth chips 510, which are sequentially stacked, may also be adhered and fixed onto the first substrate 100 by using the adhesive layer 240.

According to some embodiments, the third chip stacked structure 400 may have substantially the same structure as the first chip stacked structure 200. The fourth chip stacked structures 500 and 501 may have substantially the same structure as, or a similar structure to, the second chip stacked structures 300 and 301. According to embodiments, and there may be some differences in vertical direction thicknesses of the chips, the heights of the wires, the positions of the chip pads, or the like. Thus, such differences may be irrelevant as long as the overall structure of embodiments are substantially the same or similar.

Referring to FIGS. 3A, 4A, and 5A, the lowermost second chip 311 and a lowermost fourth chip 511 included in the second chip stacked structure 300 and the fourth chip stacked structure 500 may have greater thicknesses in the vertical direction Z than that of the second chips 310 and the fourth chips 510, which are arranged on the first substrate 100 and have different thicknesses in the vertical direction Z, respectively. For example, the second chip stacked structure 300 and the fourth chip stacked structure 500 in FIGS. 3A, 4A, and 5A may have substantially the same structure as or a similar structure to the second chip stacked structure 300 in the semiconductor package 10 described with reference to FIG. 1.

Referring to FIGS. 3B, 4B, and 5B, the second chip stacked structure 301 may further include the first spacer 350, and the fourth chip stacked structure 501 may further include a second spacer 550. The second chip stacked structure 301 and the fourth chip stacked structure 501 in FIGS. 3B, 4B, and 5B may have substantially the same structure as, or a similar structure to, the second chip stacked structure 301 of the semiconductor package 11 described with reference to FIG. 1.

Accordingly, hereinafter, descriptions of structures of the second chip stacked structures 300 and 301 and the fourth chip stacked structures 500 and 501 will not be repeated, and the arrangement of the first through fourth chip stacked structures 200, 300, 301, 400, 500, and 501 are described.

Referring to FIGS. 3A and 3B, the first direction, which is a direction where chips of the first chip stacked structure 200 and the second chip stacked structures 300 and 301 are offset-stacked, may be opposite to the second direction, which is a direction where chips of the third chip stacked structure 400 and the fourth chip stacked structures 500 and 501 are offset-stacked. For example, the first chip stacked structure 200, the second chip stacked structures 300 and 301, the third chip stacked structure 400, and the fourth chip stacked structures 500 and 501 may be arranged symmetrically with respect to a virtual line Q2 from the first substrate 100. In addition, both the first direction and the second direction may face the center of the first substrate 100. Accordingly, the first chip stacked structure 200 and the third chip stacked structure 400 may be arranged to be adjacent to each other.

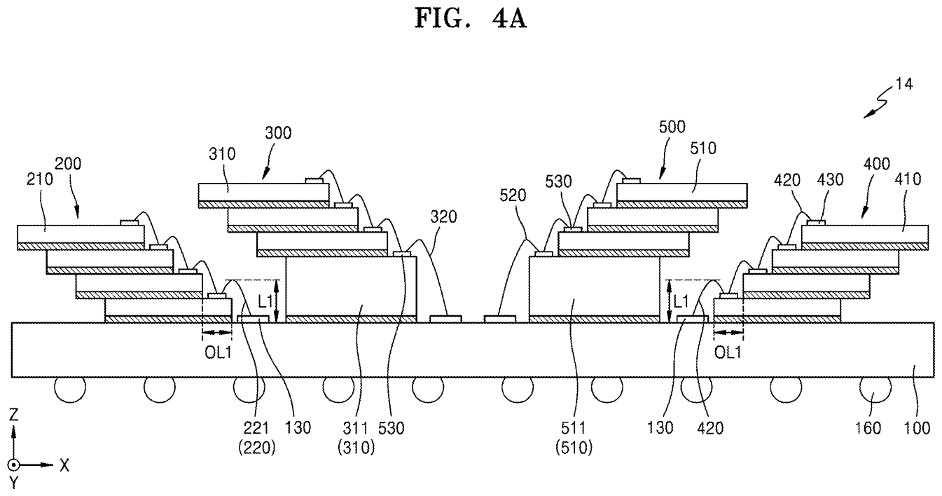

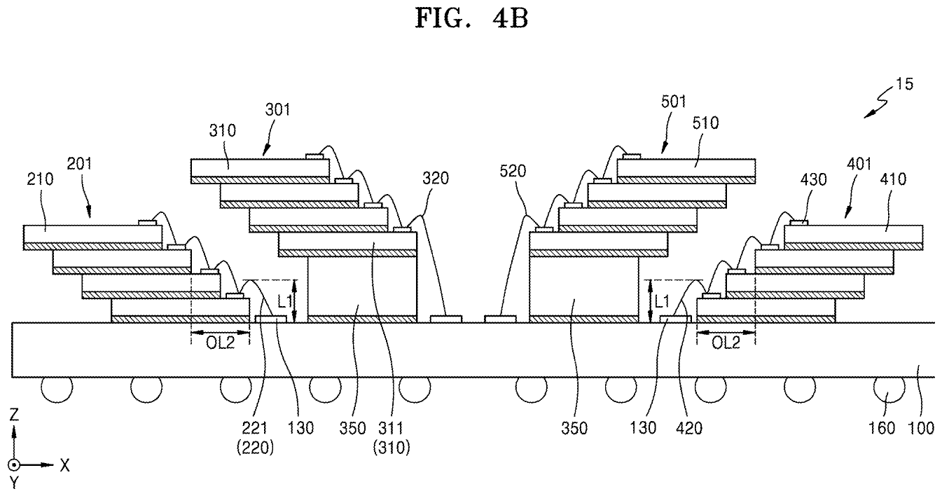

Referring to FIGS. 4A and 4B, the first direction, which is a direction where chips of the first chip stacked structure 200 and the second chip stacked structures 300 and 301 are offset-stacked, may face in a direction that is opposite to the second direction, which is a direction in which chips of the third chip stacked structure 400 and the fourth chip stacked structures 500 and 501 are offset-stacked. For example, the first chip stacked structure 200, the second chip stacked structures 300 and 301, the third chip stacked structure 400, and the fourth chip stacked structures 500 and 501 may be arranged symmetrically with respect to the virtual line Q2, on the first substrate 100. Contrary to what is shown in FIGS. 3A and 43B, in FIGS. 4A and 4B, the first direction and the second direction may face in a direction toward the outside of the first substrate 100. Accordingly, the second chip stacked structures 300 and 301 and the fourth chip stacked structures 500 and 501 may be arranged adjacent to each other.

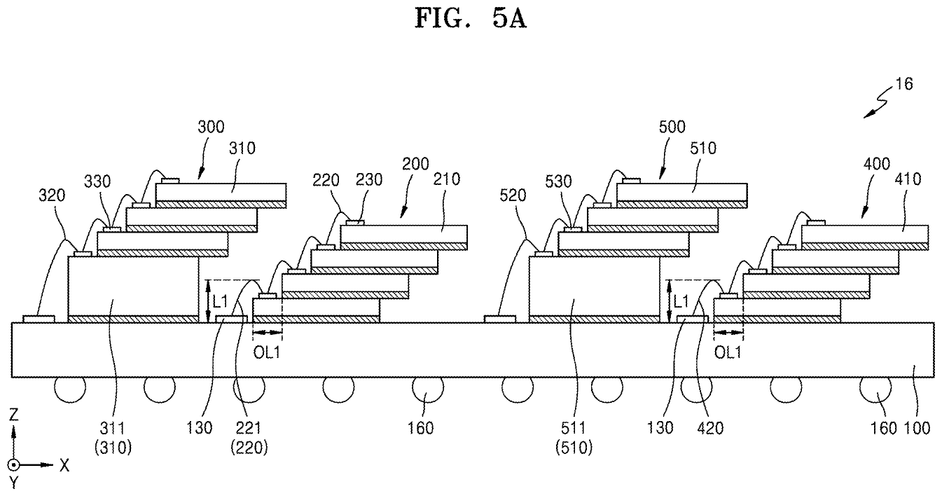

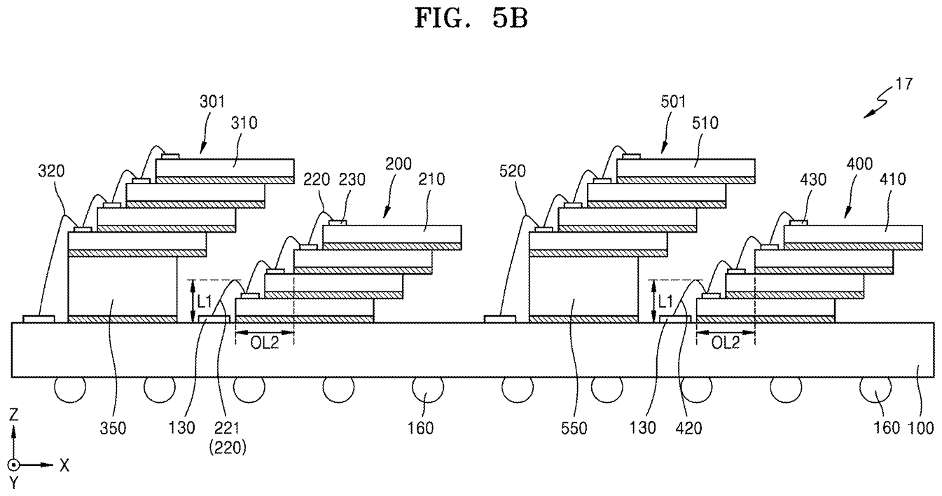

Referring to FIGS. 5A and 5B, the first direction, which is a direction in which chips of the first chip stacked structure 200 and the second chip stacked structures 300 and 301 are offset-stacked, may be substantially the same as the second direction, which is a direction where chips of the third chip stacked structure 400 and the fourth chip stacked structures 500 and 501 are offset-stacked. In this case, each of the substrate pad 130 connected to the first chip stacked structure 200, the substrate pad 130 connected to the third chip stacked structure 400, and the substrate pad 130 connected to the fourth chip stacked structures 500 and 501 may overlap any one of the first through fourth chip stacked structures 200, 300, 301, 400, 500, and 501 in the vertical direction Z.

By way of summation and review, embodiments provide a semiconductor package that allows for a package size reduction effect by changing the position and structure of a chip stacked structure. Accordingly, the sizes of semiconductor packages having changed positions and structures may be reduced.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor package comprising:
a first substrate having an upper surface and a lower surface opposite to the upper surface, and including a substrate pad arranged on the upper surface;
a first chip stacked structure mounted on the upper surface of the first substrate, the first chip stacked structure including a plurality of first chips offset-stacked in a first direction;
a lowermost first wire electrically connecting a lowermost first chip at a lowermost end among the plurality of first chips to the substrate pad; and
a second chip stacked structure mounted on the upper surface of the first substrate, the second chip stacked structure including a plurality of second chips offset-stacked in the first direction,
wherein the second chip stacked structure is spaced apart from the first chip stacked structure with the lowermost first wire therebetween in a horizontal direction, and
an upper surface of a lowermost second chip at a lowest end among the plurality of second chips is at a higher level in a vertical direction than a highest level of the lowermost first wire in the vertical direction.

2. The semiconductor package as claimed in claim 1, wherein the lowermost second chip is arranged on the upper surface of the first substrate, and a thickness of the lowermost second chip in the vertical direction is greater than a maximum height of the lowermost first wire in the vertical direction.

3. The semiconductor package as claimed in claim 2, wherein the thickness of the lowermost second chip in the vertical direction is in a range of about 500 μm to about 1000 μm.

4. The semiconductor package as claimed in claim 2, wherein at least a portion of an upper surface of the lowermost first chip overlaps the second chip stacked structure in the vertical direction.

5. The semiconductor package as claimed in claim 1, wherein the second chip stacked structure further includes a first spacer on the upper surface of the first substrate, and the lowermost second chip is arranged on an upper surface of the first spacer.

6. The semiconductor package as claimed in claim 5, wherein the upper surface of the first spacer is at a higher level in the vertical direction than a maximum height of the lowermost first wire in the vertical direction.

7. The semiconductor package as claimed in claim 5, wherein a thickness of the first spacer in the vertical direction is in a range of about 500 μm to about 1000 μm.

8. The semiconductor package as claimed in claim 5, wherein a width of the first spacer in a first horizontal direction is less than a width of the lowermost second chip in the first horizontal direction.

9. The semiconductor package as claimed in claim 8, wherein a sidewall opposite to a sidewall of the first spacer facing the first chip stacked structure, and a sidewall opposite to a sidewall of the lowermost second chip facing the first chip stacked structure are substantially coplanar.

10. The semiconductor package as claimed in claim 5, wherein at least a portion of an upper surface of the lowermost first chip overlaps the second chip stacked structure in the vertical direction.

11. A semiconductor package comprising:
a first substrate having an upper surface and a lower surface, the lower surface being opposite to the upper surface, the first substrate including a plurality of substrate pads arranged on the upper surface;
a first chip stacked structure mounted on the upper surface of the first substrate, the first substrate including a plurality of first chips offset-stacked in a first direction;
a lowermost first wire electrically connecting a lowermost first chip at a lowermost end among the plurality of first chips to the substrate pad arranged adjacent to the lowermost first chip;
a second chip stacked structure mounted on the upper surface of the first substrate and apart from the first chip stacked structure with the first wire therebetween in a horizontal direction, the second chip stacked structure including a plurality of second chips offset-stacked in the first direction;
a third chip stacked structure mounted on the upper surface of the first substrate, and including a plurality of third chips offset-stacked in a second direction;
a lowermost third wire electrically connecting a lowermost third chip at a lowermost end among the plurality of third chips to the substrate pad arranged adjacent to the lowermost third chip; and
a fourth chip stacked structure mounted on the upper surface of the first substrate and spaced apart from the third chip stacked structure with the third wire therebetween in the horizontal direction, the fourth chip stacked structure including a plurality of fourth chips offset-stacked in the second direction,
wherein an upper surface of a lowermost second chip at a lowest end among the plurality of second chips is at a higher level in a vertical direction than a maximum height of the first wire in a vertical direction, and
an upper surface of a lowermost fourth chip at a lowest end among the plurality of fourth chips is at a higher level in the vertical direction than a maximum height of the third wire in the vertical direction.

12. The semiconductor package as claimed in claim 11, wherein at least a portion of an upper surface of the lowermost first chip overlaps the second chip stacked structure in the vertical direction, and
at least a portion of an upper surface of the lowermost third chip overlaps the fourth chip stacked structure in the vertical direction.

13. The semiconductor package as claimed in claim 11, wherein the first direction and the second direction are in opposite directions to each other.

14. The semiconductor package as claimed in claim 11, wherein the first direction and the second direction are substantially identical directions.

15. The semiconductor package as claimed in claim 11, wherein the lowermost second chip is arranged on the upper surface of the first substrate, and a thickness of the lowermost second chip in the vertical direction is greater than a maximum height of the lowermost first wire in the vertical direction, and
wherein the lowermost fourth chip is arranged on the upper surface of the first substrate, and a thickness of the lowermost fourth chip in the vertical direction is greater than a maximum height of the lowermost third wire in the vertical direction.

16. The semiconductor package as claimed in claim 11, wherein the second chip stacked structure further comprises a first spacer on the upper surface of the first substrate, and the lowermost second chip is arranged on an upper surface of the first spacer, and
wherein the fourth chip stacked structure further comprises a second spacer on the upper surface of the first substrate, and the lowermost fourth chip is arranged on an upper surface of the second spacer.

17. The semiconductor package as claimed in claim 16, wherein a width of the first spacer in a first horizontal direction is less than a width of the lowermost second chip in the first horizontal direction, and
a width of the second spacer in the first horizontal direction is less than a width of the lowermost fourth chip in the first horizontal direction.

18. A semiconductor package comprising:
a first substrate having an upper surface and a lower surface opposite to the upper surface, the first substrate including a plurality of substrate pads arranged on the upper surface;
an external connection terminal arranged under the lower surface of the first substrate;
a first chip stacked structure including a plurality of first chips mounted on the upper surface of the first substrate and offset-stacked in a first direction, and first chip pads each being arranged on a region upwardly exposed on an upper surface of each of the plurality of first chips;
a lowermost first wire electrically connecting a lowermost first chip at a lowermost end among the plurality of first chips to a substrate pad arranged adjacent to the lowermost first chip;
a second chip stacked structure mounted on the upper surface of the first substrate and spaced apart in a horizontal direction from the first chip stacked structure with the first wire therebetween, the second chip stacked structure including a plurality of second chips offset-stacked in the first direction, and second chip pads each arranged on a region upwardly exposed on an upper surface of each of the plurality of second chips;
a third chip stacked structure including a plurality of third chips mounted on the upper surface of the first substrate and offset-stacked in a second direction, and third chip pads each arranged on a region upwardly exposed on an upper surface of each of the plurality of third chips;
a lowermost third wire electrically connecting a lowermost third chip at a lowermost end among the plurality of third chips to the substrate pad arranged adjacent to the lowermost third chip; and
a fourth chip stacked structure including a plurality of fourth chips mounted on the upper surface of the first substrate, spaced apart in the horizontal direction from the third chip stacked structure with the third wire therebetween, and offset-stacked in the second direction, and third chip pads each arranged on a region upwardly exposed on an upper surface of each of the plurality of fourth chips,
wherein:
an upper surface of a lowermost second chip at a lowest end among the plurality of second chips is at a higher vertical direction level than a maximum height of the first wire in the vertical direction,
an upper surface of a lowermost fourth chip at a lowest end among the plurality of fourth chips is at a higher level in the vertical direction than a maximum height of the third wire in the vertical direction,
at least a portion of an upper surface of the lowermost first chip overlaps the second chip stacked structure in the vertical direction, and
at least a portion of an upper surface of the lowermost third chip overlaps the fourth chip stacked structure in the vertical direction.

19. The semiconductor package as claimed in claim 18, wherein:
the lowermost second chip is arranged on the upper surface of the first substrate, and a thickness of the lowermost second chip in the vertical direction is greater than a maximum height of the lowermost first wire in the vertical direction, and
the lowermost fourth chip is arranged on the upper surface of the first substrate, and a thickness of the lowermost fourth chip in the vertical direction is greater than a maximum height of the lowermost third wire in the vertical direction.

20. The semiconductor package as claimed in claim 18, wherein:
the second chip stacked structure further comprises a first spacer on the upper surface of the first substrate, and the lowermost second chip is arranged on an upper surface of the first spacer, and
the fourth chip stacked structure further comprises a second spacer on the upper surface of the first substrate, and the lowermost fourth chip is arranged on an upper surface of the second spacer.
